(19) United States
(12) Patent Application Publication
(10) Pub. No.: US 2025/0338728 A1
(43) Pub. Date: Oct. 30, 2025

(54) TRANSISTOR AREA AND ELECTRONIC DEVICE INCLUDING DISPLAY DEVICE INCLUDING THEREOF

(71) Applicant: SAMSUNG DISPLAY CO., LTD., YONGIN-SI (KR)

(72) Inventor: Hee Chul LEE, Yongin-si (KR)

(21) Appl. No.: 19/073,844

(22) Filed: Mar. 7, 2025

(30) Foreign Application Priority Data
Apr. 26, 2024 (KR) 10-2024-0056219

(51) Int. Cl. H10K 59/124; H10K 59/121

(52) U.S. Cl. CPC H10K 59/124; H10K 59/1213

(57) ABSTRACT

A transistor area includes: a substrate, a first region disposed in the substrate, a first sub-region and a second sub-region, which are disposed in the substrate; a gate insulating layer disposed on the substrate; and an interlayer insulating layer disposed on the gate insulating layer. A channel length between the first region and the second sub-region is longer than a channel length between the first region and the first sub-region.

### CROSS-REFERENCE TO RELATED APPLICATION

The present application claims priority under 35 U.S.C. § 119(a) to Korean patent application No. 10-2024-0056219 filed on Apr. 26, 2024, in the Korean Intellectual Property Office, the entire disclosure of which is herein incorporated by reference.

### BACKGROUND

### 1. Technical Field

The present disclosure generally relates to transistor area and an electronic device including display device including the transistor area, and more particularly to a transistor area including a doped region having sub-regions.

### 2. Discussion of Related Art

An organic light emitting display device is a self-luminous display device which may include a hole injection electrode, an electron injection electrode, and an organic light emitting layer formed between the hole injection electrode and the electron injection electrode. The organic light emitting display device may emit light while holes injected from the hole injection electrode and electrons injected from the electron injection electrode are recombined in the organic light emitting layer. The organic light emitting display device may exhibit high-quality characteristics such as low power consumption, high luminance, and high response speed.

The organic light emitting display device may include a thin film transistor to control an operation of each pixel or to transfer an electrical signal supplied from a driver to each pixel.

### SUMMARY

Embodiments provide a transistor area capable of compensating for a degradation phenomenon caused by ultraviolet exposure.

In accordance with an aspect of the present disclosure, there is provided a transistor area including: a substrate; a first region disposed in the substrate; a first sub-region, and a second sub-region, which are disposed in the substrate; a gate insulating layer disposed on the substrate; and an interlayer insulating layer disposed on the gate insulating layer, wherein a channel length between the first region and the second sub-region is longer than a channel length between the first region and the first sub-region.

The transistor area may further include a well disposed in the substrate, wherein the first region, the first sub-region, and the second sub-region may be disposed in the well and spaced apart from each other.

The well may be a channel region and the transistor area may further comprise a gate electrode on the gate insulating layer and overlapping the channel region.

The transistor area may further include a first conductive pattern disposed on the interlayer insulating layer. The first conductive pattern may be electrically connected to the first region through a first connection portion penetrating the gate insulating layer and the interlayer insulating layer.

The transistor area may further include a second conductive pattern disposed on the interlayer insulating layer. The second conductive pattern may be electrically connected to one of the first sub-region or the second sub-region through a second connection portion penetrating the gate insulating layer and the interlayer insulating layer.

An amount of impurity in the second sub-region may be greater than an amount of impurity in the first sub-region.

The first region may be a source region, and the first sub-region and the second sub-region may correspond to a drain region.

The first region may be a drain region, and the first sub-region and the second sub-region may correspond to a source region.

The second sub-region may be disposed in a first direction with respect to the first sub-region, and the first region may be disposed in a second direction opposite to the first direction with respect to the first sub-region.

In accordance with another aspect of the present disclosure, there is provided a transistor area including: a substrate; a first doped region disposed in the substrate; a first doped sub-region and a second doped sub-region, which are disposed in the substrate; a gate insulating layer disposed on the substrate; and an interlayer insulating layer disposed on the gate insulating layer, wherein a channel length between the first doped region and the second doped sub-region is different than a channel length between the first doped region and the first doped sub-region.

The transistor area may further include a well disposed in the substrate, wherein the first doped region, the first doped sub-region, and the second doped sub-region may be disposed in the well and spaced apart from each other.

The well may be a channel region.

The transistor area may further include a first conductive pattern disposed on the interlayer insulating layer. The first conductive pattern may be electrically connected to the first doped region through a first connection portion penetrating the gate insulating layer and the interlayer insulating layer.

The transistor area may further include a second conductive pattern disposed on the interlayer insulating layer. The second conductive pattern may be electrically connected to one of the first doped sub-region or the second doped sub-region through a second connection portion penetrating the gate insulating layer and the interlayer insulating layer.

An amount of impurity in the second doped sub-region may be greater than an amount of impurity in the first doped sub-region.

The first doped region may correspond to a source region, and the first doped sub-region and the second doped sub-region may correspond to a drain region.

The first doped region may correspond to a drain region, and the first doped sub-region and the second doped sub-region may correspond to a source region

The second doped sub-region may be disposed in a first direction with respect to the first doped sub-region, and the first doped region may be disposed in a second direction opposite to the first direction with respect to the first doped sub-region.

In accordance with another aspect of the present disclosure, there is provided a transistor area including: a substrate; a well disposed in the substrate; a first region disposed in the well; a first sub-region and a second sub-region, which are disposed in the well, wherein the first region, the first sub-region, and the second sub-region are spaced apart from each other in the well, and wherein an amount of impurity in the first sub-region is different than an amount of impurity in the second sub-region; a gate insulating layer disposed on the substrate; and an interlayer insulating layer disposed on the gate insulating layer, wherein the second sub-region is disposed in a first direction with respect to the first sub-region, and the first region is disposed in a second direction opposite the first direction with respect to the first sub-region.

The transistor area may further include a first conductive pattern disposed on the interlayer insulating layer; and a second conductive pattern disposed on the interlayer insulating layer, wherein the first conductive pattern is electrically connected to the first region through a first connection portion penetrating the gate insulating layer and the interlayer insulating layer, and wherein the second conductive pattern is electrically connected to one of the first sub-region or the second sub-region through a second connection portion penetrating the gate insulating layer and the interlayer insulating layer.

### BRIEF DESCRIPTION OF THE DRAWINGS

The above and other features of the disclosure will become more apparent by describing in detail embodiments thereof with reference to the accompanying drawings, in which:

FIG. 1 is a block diagram illustrating an embodiment of a display device.

FIG. 2 is a plan view illustrating an embodiment of a display panel shown in FIG. 1.

FIG. 3 is a sectional view taken along line I-I′ shown in FIG. 2.

FIG. 4 is a view illustrating a transistor area shown in FIG. 3.

FIG. 5 is a view illustrating an embodiment of the transistor area shown in FIG. 3.

FIG. 6 is a view illustrating an embodiment of the transistor area shown in FIG. 3.

FIG. 7 is a block diagram illustrating an electronic device in accordance with embodiments of the present disclosure.

FIG. 8 is a schematic diagram illustrating an example where the electronic device of FIG. 7 is implemented as a smartphone.

FIG. 9 is a schematic diagram illustrating an example where the electronic device of FIG. 7 is a tablet computer.

### DETAILED DESCRIPTION

Hereinafter, embodiments of the present disclosure will be described in more detail with reference to the accompanying drawings. Parts that are not related to the present disclosure may be omitted from the description. In addition, the present disclosure may not be limited to exemplary embodiments described herein, but may be embodied in various different forms. Rather, exemplary embodiments described herein are provided to thoroughly and completely describe the disclosed contents and to sufficiently convey the scope of the present description to a person of ordinary skill in the art.

In the entire specification, when an element is referred to as being “connected” or “coupled” to another element, the element can be directly connected or coupled to the other element, or the elements may be indirectly connected or coupled with one or more intervening elements interposed therebetween. Technical terms used herein may be understood in the context of various embodiments, and may not be limited to specific descriptions.

It will be understood that when a component “includes” an element, it should be understood that the component may not exclude another element, and may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms may be used to distinguish one element from another element. Thus, a “first” element discussed herein could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, may be intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, embodiments of the disclosure may be described here with reference to schematic diagrams (and intermediate structures) of the present disclosure, so that changes in a shape as shown due to, for example, manufacturing technology and/or a tolerance may be expected. Therefore, embodiments of the present disclosure shall not be limited to the specific shapes of a region shown here, but include shape deviations caused by, for example, the manufacturing technology. The regions shown in the drawings are schematic in nature, and the shapes thereof may not represent the actual shapes of the regions of the device, and do not limit the scope of the disclosure.

Example embodiments will now be described more fully hereinafter with reference to the accompanying drawings; however, aspects of the drawings may be embodied in different forms and should not be construed as limited to embodiments set forth herein. Rather, embodiments are provided so that this disclosure will be thorough and complete, and will fully convey the scope of the present disclosure to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

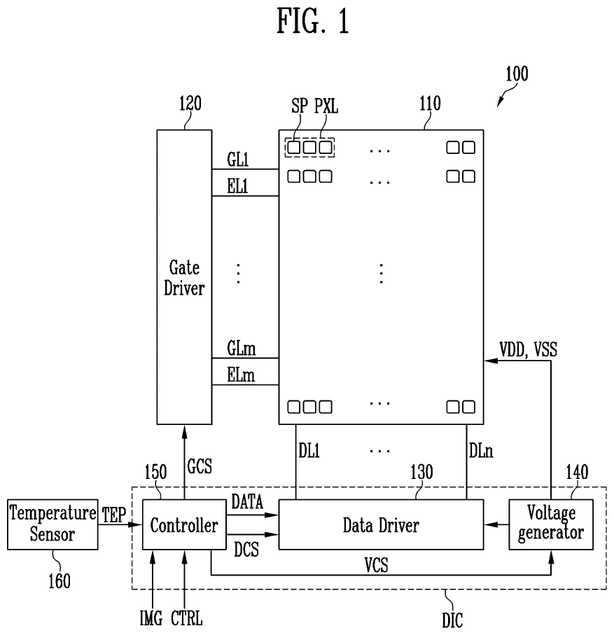

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120. The sub-pixels SP may be connected to the gate driver 120 through first to mth gate lines GL1 to GLm. The sub-pixels SP may be connected to the data driver 130. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute a pixel PXL. For example, three sub-pixels SP may constitute a pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied.

The display device 100 may include first to mth light emitting control lines EL1 to Elm. In embodiments, the first to mth light emitting control lines EL1 to ELm may be connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be disposed at a side of the display panel 110. However, embodiments are not limited thereto. For example, the gate driver 120 may be divided into two or more drivers which may be physically and/or logically divided, and these drivers may be disposed at a first side of the display panel 110 and a second side of the display panel 110, which may be opposite to the first side. As such, in some embodiments, the gate driver 120 may be disposed in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include one or more signals. For example, the data control signal DCS may include a source start pulse, a source shift clock, and a source output enable signal.

The data driver 130 may apply data signals to the image data DATA to the first to nth data lines DL1 to DLn by using voltages from the voltage generator 140. For example, the data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLm. Accordingly, corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from outside of the display device 100, adjusting the received voltage, and regulating the adjusted voltage.

The voltage generator 140 may generate a first power voltage VDD and a second power voltage VSS. The generated first and second power voltages VDD and VSS may be provided to the sub-pixels SP. The first power voltage VDD may have a relatively high voltage level, and the second power voltage VSS may have a voltage level lower than the voltage level of the first power voltage VDD. In some embodiments, the first power voltage VDD or the second power voltage VSS may be provided by an external device of the display device 100.

The voltage generator 140 may generate other voltages. For example, the voltage generator 140 may generate an initialization voltage applied to the sub-pixels SP. For example, a predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may process the input image data IMG. For example, the image data IMG may be processed to be suitable for the display device 100 or the display panel 110. The image data IMG may be output by the controller 150 as the image data DATA. For example, the image data IMG may be converted to be suitable for the display device 100 of the display panel 110 and output as the image data DATA. In embodiments, the controller 150 may align the input image data IMG to be suitable for the sub-pixels SP in units of rows, thereby outputting the image data DATA. In some embodiments, the input image data IMG may be output as the image data DATA without being processed by the controller 150.

Two or more components among the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in a driver integrated circuit DIC. In some embodiments, at least one of the data driver 130, the voltage generator 140, or the controller 150 may be provided as a component distinct from the driver integrated circuit DIC.

The display device 100 may include at least one temperature sensor 160. The temperature sensor 160 may be configured to sense a temperature and generate temperature data TEP indicating the sensed temperature. The temperature sensor 160 may be configured to sense a temperature at a periphery of the display device 100 and generate the temperature data TEP indicating the sensed temperature. In embodiments, the temperature sensor 160 may be disposed to be adjacent to the display panel 110 and/or the driver integrated circuit DIC.

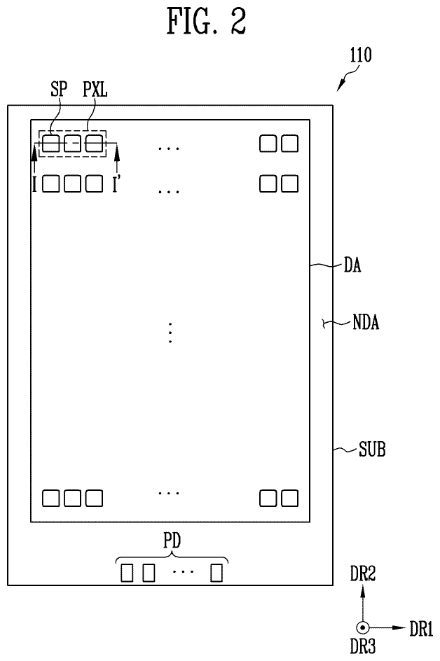

The controller 150 may control various operations of the display device 100 in response to the temperature data TEP. In embodiments, the controller 150 may adjust the luminance of an image output from the display panel 110 in response to the temperature data TEP. For example, the controller 150 may control components such as the data driver 130 and/or the voltage generator 140, thereby adjusting data signals and the first and second power voltages VDD and VSS. FIG. 2 is a plan view illustrating an embodiment of the display panel shown in FIG. 1.

Referring to FIG. 2, an embodiment of the display panel 110 shown in FIG. 1 may include a display area DA and a non-display area NDA. The display panel 110 may display an image through the display area DA. The non-display area NDA may be disposed at the periphery of the display area DA.

The display panel 110 may include a substrate SUB, sub-pixels SP, and pads PD.

In some implementations, when the display panel 110 is used as a display screen, the display panel 110 may be located close to the eyes of a user. For example, when the display panel 110 is used as a display screen of a Head Mounted Display (HMD), a Virtual Reality (VR) device, a Mixed Reality (MR) device, or an Augmented Reality (AR) device, the display panel 110 may be located close to the eyes of the user. In an implementation in which the display panel 110 may be located close to the eyes of a user, a degree of integration of the sub-pixels SP may be relatively high to maintain an image quality of a displayed image. In order to support the relatively high degree of integration of the sub-pixels SP, the substrate SUB may be provided as a silicon substrate. The sub-pixels SP and/or the display panel 110 may be formed on the substrate SUB as the silicon substrate. The display device 100 (see FIG. 1) including the display panel 110 formed on the substrate SUB provided as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a PENTILE® form. The first direction DR1 may be a row direction, and the second direction DR2 may be a column direction.

Two or more sub-pixels among the sub-pixels SP may constitute a pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, or the temperature sensor 160 (see FIG. 1), may be integrated in the non-display area NDA of the display panel 110. In embodiments, the gate driver 120 shown in FIG. 1 may be mounted on the display panel DP, and may be disposed in the non-display area NDA. In some embodiments, the gate driver 120 may be implemented as an integrated circuit distinct from the display panel 110. In embodiments, the temperature sensor 160 may be disposed in the non-display area NDA, and may sense a temperature of the display panel 110.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel 110 with other components of the display device 100 (see FIG. 1). In embodiments, voltages and signals that may be used for operations of components included in the display panel DP may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In embodiments, a circuit board may be electrically connected to the pads PD. For example, the circuit board may be electrically connected to the pads PD using a conductive adhesive member such as an anisotropic conductive film. The circuit board may be a Flexible Printed Circuit Board (FPCB) or a flexible film, which may be formed of a flexible material. The driver integrated circuit DIC may be mounted on the circuit board, and may be electrically connected to the pads PD.

In embodiments, the display area DA may have any of various shapes. The display area DA may have a closed-loop shape including linear sides and/or curved sides. For example, the display area DA may have shapes such as a polygon, a circle, a semicircle, and an ellipse.

In embodiments, the display panel 110 may have a flat display surface. In some embodiments, the display panel 110 may at least partially have a round display surface. In embodiments, the display panel 110 may be flexible. For example, the display panel 110 may be, at least in part, bendable, foldable or rollable. The display panel 110 and/or the substrate SUB may include materials having flexibility.

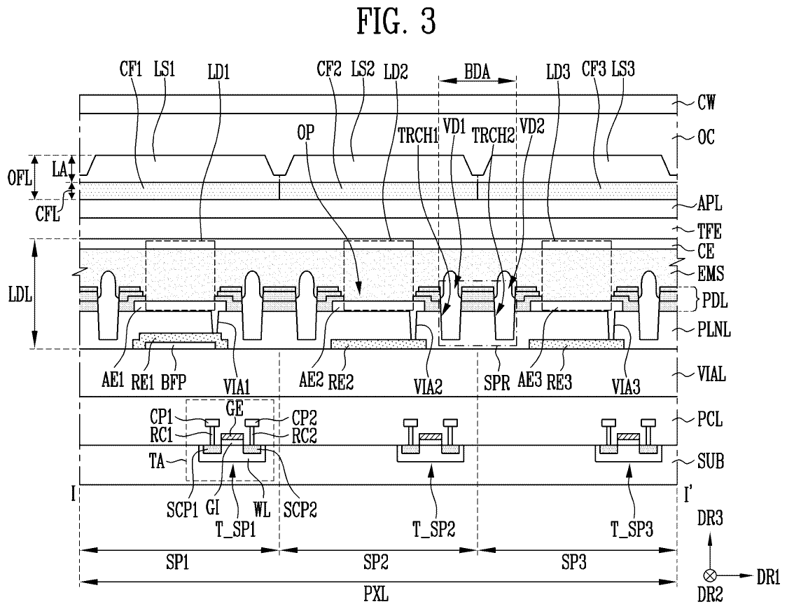

FIG. 3 is a sectional view taken along line I-I′ shown in FIG. 2.

Referring to FIG. 3, a substrate SUB and a pixel circuit layer PCL may be provided. The pixel circuit layer PCL may be disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of a first sub-pixel SP1, a second sub-pixels SP2, and a third sub-pixel SP3. Each of the first sub-pixel SP1, the second sub-pixels SP2, and the third sub-pixel SP3 may include one or more transistors. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1, the transistor T_SP2 of the second sub-pixel SP2, and the transistor T_SP3 of the third sub-pixel SP3 may be transistors of the sub-pixel circuits SP of the pixel PXL (see FIG. 2). In FIG. 3, for clear and brief description, one of the transistors of each sub-pixel SP is illustrated, and other circuit elements may be omitted.

The transistors of the sub-pixel circuits SP of the pixel PXL, e.g., the transistor T_SP1 of the first sub-pixel SP1, the transistor T_SP2 of the second sub-pixel SP2, and the transistor T_SP3 of the third sub-pixel SP3, may each include doped regions. The doped regions may be source/drain regions of the transistors.

The transistors T_SP1 of the first sub-pixel SP1 may each include a first region SCP1, a second region SCP2, and a gate electrode GE. Referring to FIG. 3, the first region SCP1 and the second region SCP2 may be doped regions of the transistor T_SP1.

The first region SCP1 and the second region SCP2 may be disposed in the substrate SUB. A well WL may be disposed in the substrate SUB. The well WL may be formed through an ion implantation process. The first region SCP1 and the second region SCP2 may be disposed in the well WL and may be spaced apart from each other. A region between the first region SCP1 and the second region SCP2 in the well WL may be defined as a channel region. In an embodiment, the first region SCP1 may be a source region, and the second region SCP2 may be a drain region. However, embodiments are not limited thereto, for example, in some embodiments the first region SCP1 may be a drain region, and the second region SCP2 may be a source region.

The gate electrode GE may overlap with the channel region between the first region SCP1 and the second region SCP2, and may be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers, and the conductive patterns may include a first conductive pattern CP1 and a second conductive pattern CP2. The first conductive pattern CP1 may be electrically connected to the first region SCP1 through a first connection portion RC1 penetrating one or more insulating layers. The second conductive pattern CP2 may be electrically connected to the second region SCP2 through a second connection portion RC2 penetrating one or more insulating layers.

As the gate electrode GE and the first and second conductive patterns CP1 and CP2 may be connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As such, the substrate SUB and/or the pixel circuit layer PCL may include circuit elements of each of the first to third sub-pixels SP1, SP2, and SP3.

A via layer VIAL may be disposed on the pixel circuit layer PCL. The via layer VIAL may cover the pixel circuit layer PCL. The via layer VIAL may have an entirely flat surface. The via layer VIAL may be configured to planarize step differences on the pixel circuit layer PCL. The via layer VIAL may include at least one of silicon oxide (SiOₓ), silicon nitride (SiNₓ), or silicon carbon nitride (SiCN), but embodiments are not limited thereto.

A light emitting element layer LDL may be disposed on the via layer VIAL. The light emitting element layer LDL may include a first reflective electrode RE1, a second reflective electrode RE2, and a third reflective electrode RE3, a planarization layer PLNL, a first anode electrode AE1, a second anode electrode AE2, and a third anode electrode AE3, a pixel defining layer PDL, a light emitting structure EMS, and a cathode electrode CE.

The first to third reflective electrodes RE1 to RE3 may be disposed on the via layer VIAL and in the first to third sub-pixels SP1 to SP3, respectively. Each of the first to third reflective electrodes RE1 to RE3 may be in contact with a circuit element disposed in the pixel circuit layer PCL through a via penetrating the via layer VIAL.

The first to third reflective electrodes RE1 to RE3 may serve as full mirrors, which may reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), or titanium (Ti), or alloys of two or more materials selected therefrom, but embodiments are not limited thereto.

In embodiments, a connection electrode may be disposed on the bottom of each of the first to third reflective electrodes RE1 to RE3. The connection electrode may improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), or tantalum nitride (TaN), but embodiments are not limited thereto. In embodiments, a corresponding reflective electrode may be disposed between multiple layers of the connection electrode.

A buffer pattern BFP may be disposed on a bottom surface of at least one of the first to third reflective electrodes RE1 to RE3A. For example, the buffer pattern BFP may be disposed on the via layer VIAL. The buffer pattern BFP may include an inorganic material such as silicon carbon nitride, but embodiments are not limited thereto. A height of the corresponding reflective electrode in a third direction DR3 may be controlled according to a height of the buffer pattern BFP. For example, the buffer pattern BFP may be disposed between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 may be effectively and efficiently output light of the corresponding wavelength range.

Referring to FIG. 3, the buffer pattern BFP may be disposed in the first sub-pixel SP1 and may be omitted from the second and third sub-pixels SP2 and SP3. However, embodiments are not limited thereto. The buffer pattern BFP may be provided in at least one of the second or third sub-pixels SP2 and SP3. The buffer pattern BFP may adjust a resonance distance of the at least one of the second or third sub-pixels SP2 and SP3. For example, the first to third sub-pixels SP1 to SP3 may respectively correspond to red, green, and blue colors. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be disposed on the via layer VIAL and the first to third reflective electrodes RE1 to RE3. The planarization layer PLNL may planarize step differences between the first to third reflective electrodes RE1 to RE3. The planarization layer PLNL may entirely cover the first to third reflective electrodes RE1 to RE3 and the via layer VIAL, and may have a flat upper surface. In embodiments, the planarization layer PLNL may be omitted.

The first to third anode electrodes AE1 to AE3 respectively overlapping with the first to third reflective electrodes RE1 to RE3 may be disposed on the planarization layer PLNL. The first to third anode electrodes AE1 to AE3 may be electrically connected to the first to third reflective electrodes RE1 to RE3, respectively. The first anode electrode AE1 may be electrically connected to the first reflective electrode RE1 through a first via VIA1 penetrating the planarization layer PLNL. The second anode electrode AE2 may be electrically connected to the second reflective electrode RE2 through a second via VIA2 penetrating the planarization layer PLNL. The third anode electrode AE3 may be electrically connected to the third reflective electrode RE3 through a third via VIA3 penetrating the planarization layer PLNL.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), or indium tin zinc oxide (ITZO), but embodiments are not limited thereto. However, the material of the first to third anode electrodes AE1 to AE3 is not limited thereto. For example, the first to third anode electrodes AE1 to AE3 may include titanium nitride.

In embodiments, insulating layers for adjusting a height of at least one of the first to third anode electrodes AE1 to AE3 may be further included. The insulating layers may be disposed between at least one of the first to third anode electrodes AE1 to AE3 and corresponding reflective electrodes. The planarization layer PLNL and/or the buffer pattern BFP may be omitted. For example, the first to third sub-pixels SP1 to SP3 may correspond to red, green, and blue colors, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1 to SP3.

In embodiments, the pixel defining layer PDL may include a plurality of inorganic insulating layers. Each of the plurality of inorganic insulating layers may include at least one of silicon oxide (SiOₓ) or silicon nitride (SiNₓ). For example, the pixel defining layer PDL may include first to third inorganic insulating layers, which may be sequentially stacked. The first to third inorganic insulating layers may include silicon nitride, silicon oxide, and silicon nitride, respectively. However, embodiments are not limited thereto. The first to third inorganic insulating layers may have a stepped section in an area adjacent to the opening OP.

A separator SPR may be disposed in a boundary area BDA between adjacent sub-pixels. In other words, the separator SPR may be provided in each boundary area between the sub-pixels SP shown in FIG. 3.

The separator SPR may cause a discontinuity to be formed in the light emitting structure EMS in the boundary areas BDA. For example, by the separator SPR, the light emitting structure EMS may be cut or bent in the boundary area BDA.

The separator SPR may be disposed in or on the pixel defining layer PDL. The pixel defining layer PDL may include one or more trenches, for example, a first trench TRCH1 and a second trench TRCH2, as the separator SPR. In embodiments, as shown in FIG. 3, one or more of the first and second trenches TRCH1 and TRCH2 may penetrate the pixel defining layer PDL, and may partially penetrate the via layer VIAL. In some embodiments, one or more of the first and second trenches TRCH1 and TRCH2 may penetrate the pixel defining layer PDL and the planarization layer PLNL, and may partially penetrate the via layer VIAL. In some embodiments, one or more of the first and second trenches TRCH1 and TRCH2 may at least partially penetrate the planarization layer PLNL and/or via layer VIAL, and a portion of the pixel defining layer PDL may be disposed in the one or more of the first and second trenches TRCH1 and TRCH2.

In FIG. 3, it is illustrated that the first and second trenches TRCH1 and TRCH2 may be provided in the boundary area BDA. However, embodiments are not limited thereto. For example, the pixel defining layer PDL may include one trench in the boundary area BDA. Alternatively, the pixel defining layer PDL may include three or more trenches in the boundary area BDA.

In some cases, discontinuities, such as a first void VD1 and a second void VD2, may be formed in the light emitting structure EMS in the boundary area BDA. For example, the first and second voids VD1 and VD2 may be formed in the first and second trenches TRCH1 and TRCH2. The first and second voids VD1 and VD2 may be formed in a portion of the first and second trenches TRCH1 and TRCH2. One or more layers of a plurality of layers stacked in the light emitting structure EMS may be cut or bent at the first and second voids VD1 and VD2. For example, at least one charge generation layer included in the light emitting structure EMS may be cut by the first and second voids VD1 and VD2. As such, portions of the light emitting structure EMS, included in the first to third sub-pixels SP1, SP2, and SP3, may be at least partially separated from each other.

In FIG. 3, it is illustrated that the first and second voids VD1 and VD2 may be formed in the light emitting structure EMS in the boundary area BDA. However, this is merely illustrative, and embodiments are not limited thereto. For example, a concave-shaped valley may be formed in the light emitting structure EMS in the boundary area BDA. The discontinuities formed in the light emitting structure EMS may be variously changed according to shapes of the first and second trenches TRCH1 and TRCH2.

In embodiments, the light emitting structure EMS may be formed through a process such as vacuum deposition or inkjet printing. The same materials as the light emitting structure EMS may be disposed on bottom surfaces adjacent to the via layer VIAL among the first and second trenches TRCH1 and TRCH2.

The separator SPR may be variously modified. The separator SPR may be variously modified such that the light emitting structure EMS may have a discontinuity in the boundary area BDA. In embodiments, inorganic insulating patterns additionally stacked on the pixel defining layer PDL without the first and second trenches TRCH1 and TRCH2 may be disposed in the boundary area BDA. A width of an inorganic insulating pattern at an uppermost portion among the additionally stacked inorganic insulating patterns may be greater than a width of an inorganic insulating pattern disposed immediately under the inorganic insulating pattern at the uppermost portion. For example, in the boundary area BDA, first to third inorganic insulating patterns may be sequentially stacked from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA, but the present disclosure is not limited thereto. According to the shape of the pixel defining layer PDL, the plurality of layers included in the light emitting structure EMS may be partially cut or bent in the boundary area BDA.

The light emitting structure EMS may be disposed on the anode electrodes AE exposed by the openings OP of the pixel defining layer PDL. The light emitting structure EMS may be disposed in the openings OP of the pixel defining layer PDL. The light emitting structure EMS may fill the openings OP of the pixel defining layer PDL, and may be entirely disposed throughout the first to third sub-pixels SP1 to SP3. As described herein, the light emitting structure EMS may be at least partially cut or bent by the separator SPR in the boundary area BDA. Accordingly, in an operation of the display panel DP, a current leaked from each of the first to third sub-pixels SP1 to SP3 to a sub-pixel adjacent thereto through layers included in the light emitting structure EMS may be reduced. Thus, a first light emitting element LD1, a second light emitting element LD2, and a third light emitting element LD3 may operate with relatively high reliability.

The cathode electrode CE may be disposed over the light emitting structure EMS. The cathode electrode CE may be commonly provided in the first to third sub-pixels SP1 to SP3. The cathode electrode CE may serve as a half mirror, which may allow light emitted from the light emitting structure EMS to be partially transmitted therethrough and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may form the first light emitting element LD1. The second anode electrode AE2, a portion of the light emitting structure EMS, which overlaps with the second anode electrode AE2, and a portion of the cathode electrode CE, which overlaps with the second anode electrode AE2, may form the second light emitting element LD2. The third anode electrode AE3, a portion of the light emitting structure EMS, which overlaps with the third anode electrode AE3, and a portion of the cathode electrode CE, which overlaps with the third anode electrode AE3, may form the third light emitting element LD3.

An encapsulation layer TFE may be disposed on the cathode electrode CE. The encapsulation layer TFE may inhibit or prevent oxygen and/or moisture from infiltrating into the light emitting element layer LDL.

An optical functional layer OFL may be disposed on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include a first color filter CF1, a second color filter CF2, and a third color filter CF3, respectively corresponding to the first to third sub-pixels SP1 to SP3. The first to third color filters CF1 to CF3 may allow lights having different wavelength ranges to pass therethrough. For example, the first to third color filters CF1 to CF3 may allow light red, green, and blue light to pass therethrough, respectively.

In at least one embodiment, the first to third color filters CF1 to CF3 may partially overlap may be disposed adjacent to each other. For example, edge portions of the first to third color filters CF1 to CF3 may meet in the boundary area BDA. In some embodiments, the first to third color filters CF1 to CF3 may partially overlap with each other in the boundary area BDA. In one or more embodiments, the first to third color filters CF1 to CF3 may be spaced apart from each other, and a black matrix may be disposed between the first to third color filters CF1 to CF3. For example, the black matrix may be disposed in the boundary area BDA.

A lens array LA may be disposed on the color filter layer CFL. The lens array LA may include a first lens LS1, a second lens LS2, and a third lens LS3, respectively corresponding to the first to third sub-pixels SP1 to SP3. The first to third lenses LS1 to LS3 may respectively output light emitted from the first to third light emitting layers LD1 to LD3 along respective paths, thereby improving light emission efficiency.

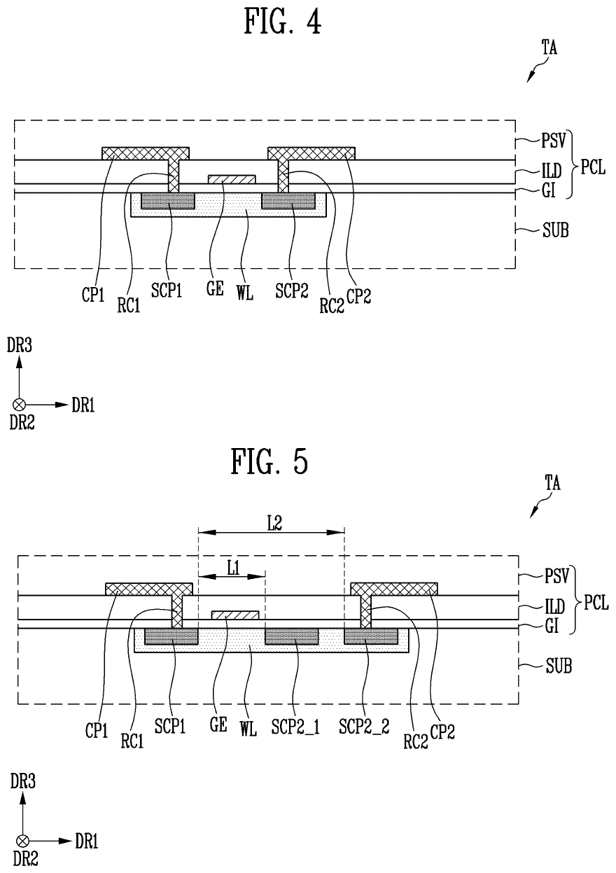

FIG. 4 is a view illustrating a transistor area shown in FIG. 3.

Referring to FIG. 4, a transistor area TA may include a first region SCP1 and a second region SCP2. The transistor area TA shown in FIG. 4 may correspond to the transistor area TA and the transistor T_SP1 shown in FIG. 3.

A pixel circuit layer PCL disposed on the substrate SUB may further include a gate insulating layer GI, an interlayer insulating layer ILD, and a passivation layer PSV.

The interlayer insulating layer ILD may be disposed on the gate insulating layer GI. In an embodiment, the interlayer insulating layer ILD may be an inorganic insulating layer including an inorganic material, but the present disclosure is not limited thereto. In some embodiments, the interlayer insulating layer ILD may be an organic insulating layer including an organic material. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, or benzocyclobutene resin.

A first conductive pattern CP1 and a second conductive pattern CP2 may be disposed on the interlayer insulating layer ILD. The first conductive pattern CP1 may be electrically connected to the first region SCP1 through a first connection portion RC1 penetrating the gate insulating layer GI and the interlayer insulating layer ILD. The second conductive patter CP2 may be electrically connected to the second region SCP2 through a second connection portion RC2 penetrating the gate insulating layer GI and the interlayer insulating layer ILD.

The passivation layer PSV may be disposed on the interlayer insulating layer ILD. In an embodiment, the passivation layer PSV may include an inorganic protective layer and an organic protective layer provided on the inorganic protective layer. The inorganic protective layer may include at least one of silicon oxide or silicon nitride. The organic protective layer may include one of acryl, polyimide (PI), polyamide (PA), or benzocyclobutene (BCB). The organic protective layer may be transparent and may have liquidity. For example, the organic protective layer may be a planarization layer capable of reducing and planarizing bending of a lower structure.

When the substrate SUB including a silicon wafer substrate is exposed to ultraviolet light, pairs of electrons and holes may be generated inside the substrate SUB. The pairs of electrons and holes, which are generated inside the substrate SUB, may allow holes to move through a lower portion of a channel region between the first region SCP1 and SPC2. Accordingly, a channel length of the transistor T_SP1 may be decreased, and a threshold voltage of the transistor T_SP1 may be increased. Stated another way, a channel length and a threshold voltage of the transistor T_SP1 may be degraded by exposure to ultraviolet light. Further, a luminance level expressed by the sub-pixel in which the transistor T_SP1 is disposed may vary. For example, the luminance level expressed by the sub-pixel in which the transistor T_SP1 is disposed may be different from a luminance level expressed by another sub-pixel. In some embodiments, the decrease in channel length and the increase in threshold voltage of the transistor T_SP1 degraded by ultraviolet exposure may be compensated for, and the sub-pixels SP of a pixel PXL may express a uniform luminance level.

FIG. 5 is a view illustrating an embodiment of the transistor area shown in FIG. 3.

Referring to FIG. 5, a transistor area TA may include a first doped region, a first doped sub-region and a second doped sub-region. For example, the transistor area TA may include a first region SCP1, a first sub-region SCP2_1, and a second sub-region SCP2_2. The transistor area TA shown in FIG. 5 may correspond to the transistor area TA and the transistor T_SP1 shown in FIG. 3.

The first region SCP1 shown in FIG. 5 may be similar to the first region SCP1 shown in FIG. 4, the first sub-region SCP2_1 shown in FIG. 5 may be similar to the second region SCP2 shown in FIG. 4, and a pixel circuit layer PCL shown in FIG. 5 may be similar to the pixel circuit layer PCL shown in FIG. 4. Repetitive or duplicate detailed descriptions of the first region SCP1, the first sub-region SCP2_1, and the pixel circuit layer PCL may be omitted or simplified.

The first region SCP1, the first sub-region SCP2_1, and the second sub-region SCP2_2 may be disposed in the substrate SUB. A well WL may be disposed in the substrate. The well WL may be formed through an ion implantation process. The first region SCP1, the first sub-region SCP2_1, and the second sub-region SCP2_2 may be disposed in the well WL. The first region SCP1, the first sub-region SCP2_1, and the second sub-region SCP2_2 may be disposed in the well WL and spaced apart from each other. The second sub-region SCP2_2 may be disposed in the first direction DR1 with respect to the first sub-region SPC2_1. In an embodiment, the first region SCP1 may be a source region, and the first sub-region SCP2_1 and the second sub-region SCP2_2 may correspond to a drain region.

A channel length L2 between the first region SCP1 and the second sub-region SCP2_2 may be different than a channel length L1 between the first region SCP1 and the first sub-region SCP2_1. For example, channel length L2 between the first region SCP1 and the second sub-region SCP2_2 may be longer than a channel length L1 between the first region SCP1 and the first sub-region SCP2_1. A degree to which the channel length L2 may be decreased by degradation may be about equal to a degree to which the channel length L1 may be decreased by degradation.

Although the channel length L2 between the first region SCP1 and the second sub-region SCP2_2 may be decreased by the degradation, the decreased channel length may be about equal to the channel length L1 between the first region SCP1 and the first sub-region SCP2_1. Accordingly, a decrease in channel length and an increase of threshold voltage of the transistor T_SP1 according to ultraviolet exposure may be compensated for by forming a channel between the first region SCP1 and the second sub-region SCP2_2, which in a degraded state has the decreased channel length about equal to the channel length L1.

In an embodiment, in the case of a transistor degraded by ultraviolet exposure, a second conductive pattern CP2 may be connected to the second sub-region SCP2_2. In the case of a transistor which is not degraded, the second conductive pattern CP2 may be connected to the first sub-region SCP2_1. That is, one of the first sub-region SCP2_1 or the second sub-region SCP2_2 may be selected according to a degree of degradation of the transistor, and the selected region may be connected to the second conductive pattern CP2. In an embodiment, a channel length and a threshold voltage may be substantially maintained during ultraviolet exposure, and sub-pixels can express a relatively uniform luminance level.

In an embodiment, an amount of impurity doped or implanted into the second sub-region SCP1_2 may be different than an amount of impurity doped or implanted into the first sub-region SCP1_1. For example, an amount of impurity doped or implanted into the second sub-region SCP2_2 may be greater than an amount of impurity doped or implanted into the first sub-region SCP2_1. For example, the amount of impurity doped or implanted into the second sub-region SCP2_2 may be sufficient such that although the channel length L2 between the first region SCP1 and the second sub-region SCP2_2 may be decreased by exposure of the transistor T_SP1 according to ultraviolet light, the decreased channel length may be about equal to the channel length L1 between the first region SCP1 and the first sub-region SCP2_1 prior to any degradation.

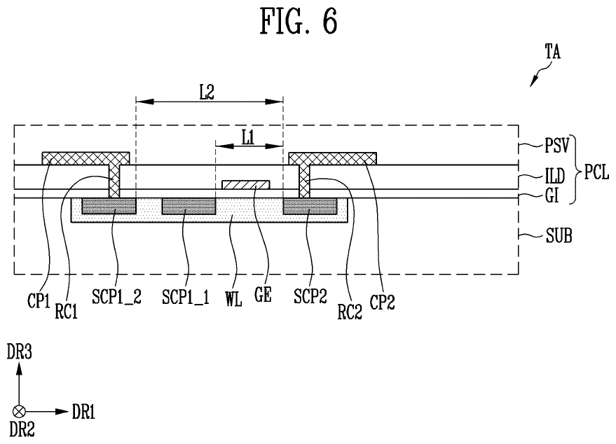

FIG. 6 is a view illustrating an embodiment of the transistor area shown in FIG. 3.

Referring to FIG. 6, a transistor area TA may include a first sub-region SCP1_1, a second sub-region SCP1_2, and a second region SCP2. The transistor area TA shown in FIG. 6 may correspond to the transistor area TA and the first transistor T_SP1 shown in FIG. 3.

The first sub-region SCP1_1 shown in FIG. 6 may be similar to the first region SCP1 shown in FIG. 4, the second region SCP2 shown in FIG. 6 may be similar to the second region SCP2 shown in FIG. 4, and a pixel circuit layer PCL shown in FIG. 6 may be similar to the pixel circuit layer PCL shown in FIG. 4. Repetitive or duplicate detailed descriptions of the first sub-region SCP1_1, the second region SCP2, and the pixel circuit layer PCL may be omitted or simplified.

The first sub-region SCP1_1, the second sub-region SCP1_2, and the second region SCP2 may be disposed in the substrate SUB. A well WL may be disposed in the substrate SUB. The well WL may be formed through an ion implantation process. The substrate SUB, and the first sub-region SCP1_1, the second sub-region SCP1_2, and the second region SCP2 may be disposed in the well WL. The substrate SUB, and the first sub-region SCP1_1, the second sub-region SCP1_2, and the second region SCP2 may be disposed in the well WL and spaced apart from each other. The second sub-region SCP1_2 may be disposed in a second direction opposite to the first direction DR1 with respect to the first sub-region SCP1_1. In an embodiment, the first sub-region SCP1_1 and the second sub-region SCP1_1 may correspond to a source region, and the second region SCP2 may be a drain region.

A channel length L2 between the second sub-region SCP1_2 and the second region SCP2 may be different than a channel length L1 between the first sub-region SCP1_1 and the second region SCP2. For example, the channel length L2 between the second sub-region SCP1_2 and the second region SCP2 may be longer than a channel length L1 between the first sub-region SCP1_1 and the second region SCP2. A degree to which the channel length L2 may be decreased by degradation may be about equal to a degree to which the channel length L1 may be decreased by degradation.

Although the channel length L2 between the second sub-region SCP1_2 and the second region SCP2 may be decreased by the degradation, the decreased channel length may be about equal to the channel length L1 between the first sub-region SCP1_1 and the second region SCP2. Accordingly, a decrease in channel length and an increase in threshold voltage of the transistor T_SP1 according to ultraviolet exposure may be compensated for by a channel formed between the second sub-region SCP1_2 and the second region SCP2, which in a degraded state has the decreased channel length about equal to the channel length L1.

In an embodiment, in the case of a transistor degraded by ultraviolet exposure, a first conductive pattern CP1 may be connected to the second sub-region SCP1_2. In the case of a transistor which is not degraded, the first conductive pattern CP2 may be connected to the first sub-region SCP1_1. That is, one of the first sub-region SCP1_1 and the second sub-region SCP1_2 may be selected according to a degree of degradation of the transistor, and the selected region may be connected to the first conductive pattern CPL. In an embodiment, a channel length and a threshold voltage of a transistor of a sub-pixel may be substantially maintained during ultraviolet exposure, and the sub-pixel can express a relatively uniform luminance level. For example, the transistor of the sub-pixel may have relatively the same channel length and relatively the same threshold voltage, and the sub-pixel can express a relatively uniform luminance level. Here, “relatively the same”, “relatively uniform”, and “substantially maintained” may be measured understood based on the luminance level of the sub-pixel using different selectable sub-regions in different conditions, e.g., based on exposure to ultraviolet light. For example, one sub-region of the sub-pixel may be used in the absence of ultraviolet light and another sub-region of the sub-pixel may be used in the presence of ultraviolet light. A sub-region may be selected such that the sub-pixel may have relatively the same channel length and relatively the same threshold voltage regardless of the absence or presence of ultraviolet exposure, and the sub-pixel may express a uniform luminance level. For example, a sub-region may be selected to improve a uniformity in the luminance level of the sub-pixel and/or the pixel.

In an embodiment, an amount of impurity doped or implanted into the second sub-region SCP1_2 may be greater than an amount of impurity doped or implanted into the first sub-region SCP1_1.

In the transistor area in accordance with the present disclosure, a degradation phenomenon caused by ultraviolet exposure may be compensated for, and the luminance of the display device can be uniformly controlled.

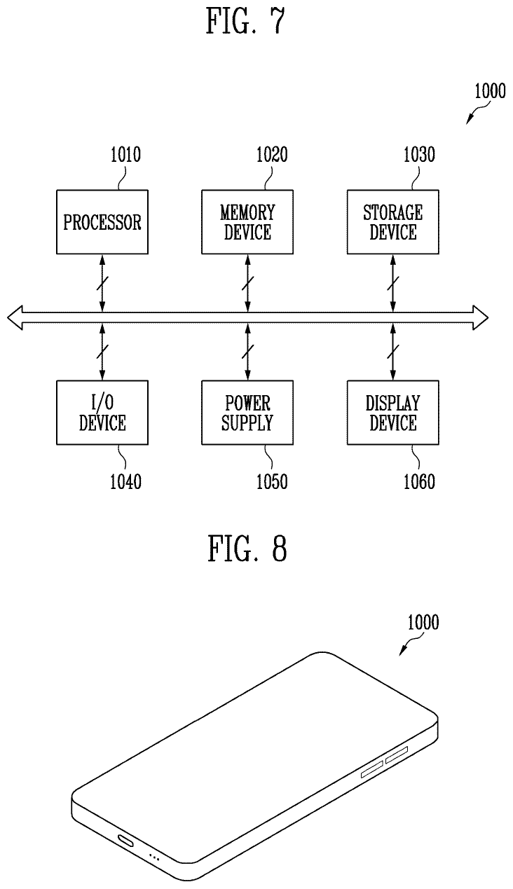

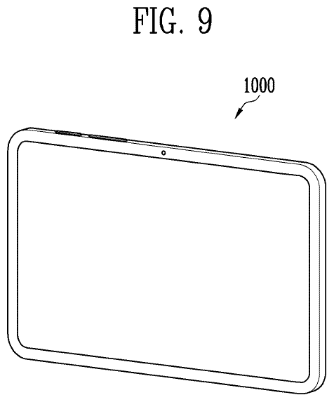

FIG. 7 is a block diagram illustrating an electronic device 1000 in accordance with embodiments of the present disclosure. FIG. 8 is a diagram illustrating an example where the electronic device 1000 of FIG. 7 is a smartphone. FIG. 9 is a schematic diagram illustrating an example where the electronic device 1000 of FIG. 7 is a tablet computer.

Referring to FIGS. 7 to 9, the electronic device 1000 may include a processor 1010, a memory device 1020, a storage device 1030, an input/output (I/O) device 1040, a power supply device 1050, and a display device 1060. The display device 1060 may be the display device of FIG. 1. The electronic device 1000 may further include various ports for communication with a video card, a sound card, a memory card, a USB device, or other systems. In an embodiment, as illustrated in FIG. 8, the electronic device 1000 may be implemented as a smartphone. In an embodiment, as illustrated in FIG. 9, the electronic device 1000 may be implemented as a table computer. However, the aforementioned examples are illustrative, and the electronic device 1000 is not limited to the aforementioned examples. For example, the electronic device 1000 may be implemented as a cellular phone, a video phone, a smart pad, a smartwatch, a navigation device for vehicles, a computer monitor, a laptop computer, a head-mounted display device, and so on.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with embodiments unless otherwise specifically indicated. Accordingly, it will be understood by those of skill in the art that various changes in form and details may be made without departing from the spirit and scope of the present disclosure as set forth in the following claims.

What is claimed is:

1. A transistor area comprising:
a substrate;
a first region disposed in the substrate;
a first sub-region and a second sub-region, which are disposed in the substrate;
a gate insulating layer disposed on the substrate; and
an interlayer insulating layer disposed on the gate insulating layer,
wherein a channel length between the first region and the second sub-region is longer than a channel length between the first region and the first sub-region.

2. The transistor area of claim 1, further comprising a well disposed in the substrate, wherein the first region, the first sub-region, and the second sub-region are disposed in the well and spaced apart from each other.

3. The transistor area of claim 2, wherein the well is a channel region and the transistor area further comprises a gate electrode on the gate insulating layer and overlapping the channel region.

4. The transistor area of claim 1, further comprising a first conductive pattern disposed on the interlayer insulating layer,
wherein the first conductive pattern is electrically connected to the first region through a first connection portion penetrating the gate insulating layer and the interlayer insulating layer.

5. The transistor area of claim 4, further comprising a second conductive pattern disposed on the interlayer insulating layer,
wherein the second conductive pattern is electrically connected to one of the first sub-region or the second sub-region through a second connection portion penetrating the gate insulating layer and the interlayer insulating layer.

6. The transistor area of claim 1, wherein an amount of impurity in the second sub-region is greater than an amount of impurity in the first sub-region.

7. The transistor area of claim 1, wherein the first region is a source region, and the first sub-region and the second sub-region correspond to a drain region.

8. The transistor area of claim 1, wherein the first region is a drain region, and the first sub-region and the second sub-region correspond to a source region.

9. The transistor area of claim 1, wherein the second sub-region is disposed in a first direction with respect to the first sub-region, and the first region is disposed in a second direction opposite to the first direction with respect to the first sub-region.

10. A transistor area comprising:
a substrate;
a first doped region disposed in the substrate;
a first doped sub-region and a second doped sub-region, which are disposed in the substrate;
a gate insulating layer disposed on the substrate; and
an interlayer insulating layer disposed on the gate insulating layer,
wherein a channel length between the first doped region and the second doped sub-region is different than a channel length between the first doped region and the first doped sub-region.

11. The transistor area of claim 10, further comprising a well disposed in the substrate, wherein the first doped region, the first doped sub-region, and the second doped sub-region are disposed in the well and spaced apart from each other.

12. The transistor area of claim 11, wherein the well is a channel region.

13. The transistor area of claim 10, further comprising a first conductive pattern disposed on the interlayer insulating layer,
wherein the first conductive pattern is electrically connected to the first doped region through a first connection portion penetrating the gate insulating layer and the interlayer insulating layer.

14. The transistor area of claim 13, further comprising a second conductive pattern disposed on the interlayer insulating layer,
wherein the second conductive pattern is electrically connected to one of the first doped sub-region or the second doped sub-region through a second connection portion penetrating the gate insulating layer and the interlayer insulating layer.

15. The transistor area of claim 10, wherein an amount of impurity in the second doped sub-region is greater than an amount of impurity in the first doped sub-region.

16. The transistor area of claim 10, wherein the first doped region is a source region, and the first doped sub-region and the second doped sub-region correspond to a drain region.

17. The transistor area of claim 10, wherein the first doped region is a drain region, and the first doped sub-region and the second doped sub-region correspond to a source region.

18. The transistor area of claim 11, wherein the second doped sub-region is disposed in a first direction with respect to the first doped sub-region, and the first doped region is disposed in a second direction opposite to the first direction with respect to the first doped sub-region.

19. A transistor area comprising:
a substrate;
a well disposed in the substrate;
a first region disposed in the well;
a first sub-region and a second sub-region, which are disposed in the well, wherein the first region, the first sub-region, and the second sub-region are spaced apart from each other in the well, and wherein an amount of impurity in the first sub-region is different than an amount of impurity in the second sub-region;
a gate insulating layer disposed on the substrate; and
an interlayer insulating layer disposed on the gate insulating layer,
wherein the second sub-region is disposed in a first direction with respect to the first sub-region, and the first region is disposed in a second direction opposite the first direction with respect to the first sub-region.

20. The transistor area of claim 19, further comprising:
a first conductive pattern disposed on the interlayer insulating layer; and
a second conductive pattern disposed on the interlayer insulating layer,
wherein the first conductive pattern is electrically connected to the first region through a first connection portion penetrating the gate insulating layer and the interlayer insulating layer, and
wherein the second conductive pattern is electrically connected to one of the first sub-region or the second sub-region through a second connection portion penetrating the gate insulating layer and the interlayer insulating layer.
